(19) United States
(12) Patent Application Publication
(10) Pub. No.: US 2024/0192054 A1
(43) Pub. Date: Jun. 13, 2024

(54) LIGHT DETECTION APPARATUS AND ELECTRONIC DEVICE

(71) Applicant: SONY SEMICONDUCTOR SOLUTIONS CORPORATION, KANAGAWA (JP)

(72) Inventor: DAIZO TAKATA, KUMAMOTO (JP)

(21) Appl. No.: 18/554,354

(22) PCT Filed: Jan. 11, 2022
(86) PCT No.: PCT/JP2022/000451

§ 371 Date: Oct. 6, 2023

(30) Foreign Application Priority Data
Apr. 20, 2021 (JP) 2021-071226

(51) Int. Cl. G01J 1/44

(52) U.S. Cl. CPC G01J 1/44

(57) ABSTRACT

A light detection apparatus is provided which improves quantum efficiency QE while suppressing light color mixing. The apparatus has multiple pixels including a first and a second pixel, the first pixel receiving, out of incident light thereon, either full-spectrum light or light having a peak wavelength in a wavelength region equal to or higher than a predetermined wavelength, the second pixel receiving, out of the incident light thereon, light having a peak wavelength in a wavelength region lower than the predetermined wavelength. The distances between the widthwise centers of multiple cross sections of the light blocking film in parallel with the light receiving surface of the substrate, the cross sections being perpendicular to the light receiving surface, are first distances each constituting the same distance. The distance between the widthwise centers of two cross sections of the pixel separation part that are perpendicular to the light receiving surface of the substrate and positioned surrounding the photoelectric conversion part in the first pixel is a second distance different from the first distance.

### TECHNICAL FIELD

The present disclosure relates to a light detection apparatus and an electronic device.

### BACKGROUND ART

Recent years have seen increasing use of devices (light detection apparatus) targeted to detect long-wavelength light. Long-wavelength light is difficult to be absorbed by silicon. For this reason, when long-wavelength light is incident on a photoelectric conversion part of the light detection apparatus, the incident light passes through the photoelectric conversion part and exits to an adjacent photoelectric conversion part, which can reduce quantum efficiency QE. When the exited light is detected by the adjacent photoelectric conversion part, light color mixing (crosstalk) can take place.

A technology has been proposed (see PTL 1) which has a pixel separation part positioned between the photoelectric conversion parts as one way to improve quantum efficiency QE while suppressing light color mixing (crosstalk). The technology described in PTL 1 involves causing the pixel separation part to reflect the light incident thereon after passing through the photoelectric conversion part, thereby allowing the reflected incident light to return to the photoelectric conversion part so as to improve quantum efficiency QE while suppressing light color mixing (crosstalk).

### CITATION LIST

### Patent Literature

[PTL 1]
Japanese Patent Laid-open No. 2017-191950

### SUMMARY

### Technical Problem

However, the predominant factor at work when long-wavelength light incurs the drop in quantum efficiency QE and causes light color mixing is the light component reflected by the wiring in the wiring layer or by an interfacial boundary between the substrate and the wiring layer. It follows that the technology described in PTL 1 (photoelectric conversion part) is not sufficient in improving quantum efficiency QE or suppressing light color mixing.

An object of the present disclosure is to provide a light detection apparatus and an electronic device capable of suppressing light color mixing while improving quantum efficiency QE.

### Solution to Problem

According to the present disclosure, there is provided a light detection apparatus including (a) a substrate, (b) multiple pixels configured to be arrayed two-dimensionally on the substrate and each have a photoelectric conversion part, (c) a light blocking film configured to be arranged on a side of a light receiving surface of the substrate and have an opening of the same shape for each of the pixels, and (d) a pixel separation part configured to be arranged between the photoelectric conversion parts on the substrate and have a trench, in which (e) the multiple pixels include a first pixel and a second pixel, the first pixel receiving, out of incident light thereon, either full-spectrum light or light having a peak wavelength in a wavelength region equal to or higher than a predetermined wavelength, the second pixel receiving, out of the incident light thereon, light having a peak wavelength in a wavelength region lower than the predetermined wavelength, (f) distances between the widthwise centers of multiple cross sections of the light blocking film in parallel with the light receiving surface of the substrate, the cross sections being perpendicular to the light receiving surface, are first distances each constituting the same distance, and (g) a distance between the widthwise centers of two cross sections of the pixel separation part that are perpendicular to the light receiving surface of the substrate and positioned surrounding the photoelectric conversion part in the first pixel is a second distance different from the first distance.

According to the present disclosure, there is provided an electronic device that has a light detection apparatus including (a) a substrate, (b) multiple pixels configured to be arrayed two-dimensionally on the substrate and each have a photoelectric conversion part, (c) a light blocking film configured to be arranged on the side of a light receiving surface of the substrate and have an opening of the same shape for each of the pixels, and (d) a pixel separation part configured to be arranged between the photoelectric conversion parts on the substrate and have a trench, in which (e) the multiple pixels include a first pixel and a second pixel, the first pixel receiving, out of incident light thereon, either full-spectrum light or light having a peak wavelength in a wavelength region equal to or higher than a predetermined wavelength, the second pixel receiving, out of the incident light thereon, light having a peak wavelength in a wavelength region lower than the predetermined wavelength, (f) distances between the widthwise centers of multiple cross sections of the light blocking film in parallel with the light receiving surface of the substrate, the cross sections being perpendicular to the light receiving surface, are first distances each constituting the same distance, and (g) the distance between the widthwise centers of two cross sections of the pixel separation part that are perpendicular to the light receiving surface of the substrate and positioned surrounding the photoelectric conversion part in the first pixel is a second distance different from the first distance.

### BRIEF DESCRIPTION OF DRAWINGS

FIG. 1 is an overall configuration view of a solid-state imaging apparatus as a first embodiment of the present disclosure.

FIG. 2 is a cross-sectional view of the solid-state imaging apparatus taken on line A-A in FIG. 1.

FIG. 3 is a cross-sectional view of the solid-state imaging apparatus taken on line B-B in FIG. 2.

FIG. 4 is a cross-sectional view of the solid-state imaging apparatus taken on line C-C in FIG. 2.

FIG. 5 is a cross-sectional view of the solid-state imaging apparatus taken on line D-D in FIG. 2.

FIG. 6 is a cross-sectional view of an existing solid-state imaging apparatus.

FIG. 7 is a cross-sectional view of an alternative example of the solid-state imaging apparatus taken on line A-A in FIG. 1.

FIG. 8 is a cross-sectional view of an alternative example of the solid-state imaging apparatus taken on line A-A in FIG. 1.

FIG. 9 is a cross-sectional view of an alternative example of the solid-state imaging apparatus taken on line E-E in FIG. 8.

FIG. 10 is a cross-sectional view of another existing solid-state imaging apparatus.

FIG. 11 is a cross-sectional view of an alternative example of the solid-state imaging apparatus taken on line A-A in FIG. 1.

FIG. 12 is a cross-sectional view of an alternative example of the solid-state imaging apparatus taken on line D-D in FIG. 2.

FIG. 13 is a cross-sectional view of an alternative example of the solid-state imaging apparatus taken on line D-D in FIG. 2.

FIG. 14 is a cross-sectional view of an alternative example of the solid-state imaging apparatus taken on line B-B in FIG. 2.

FIG. 15 is a cross-sectional view of an alternative example of the solid-state imaging apparatus taken on line A-A in FIG. 1.

FIG. 16 is a cross-sectional view of an alternative example of the solid-state imaging apparatus taken on line F-F in FIG. 15.

FIG. 17 is a cross-sectional view of an alternative example of the solid-state imaging apparatus taken on line G-G in FIG. 15.

FIG. 18 is a schematic configuration diagram of an electronic device as a second embodiment of the present disclosure.

### DESCRIPTION OF EMBODIMENTS

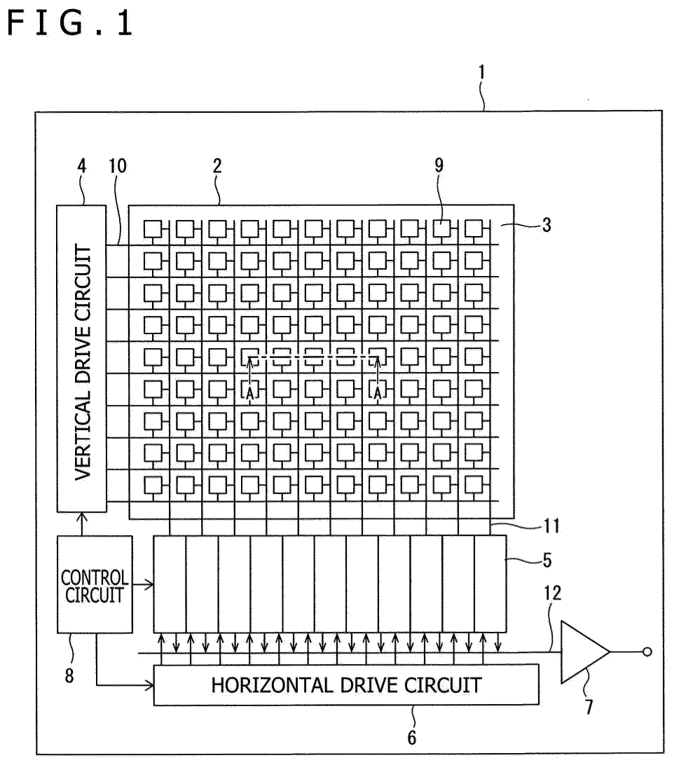

Described below with reference to FIGS. 1 through 18 are an exemplary light detection apparatus and an exemplary electronic device as preferred embodiments of the present disclosure. The description of the embodiments of this disclosure will be given in the order below. The present disclosure is not limited to the examples that follow. The advantageous effects stated in this description are only examples and are not limitative of the present disclosure. There may be additional advantageous effects derived from and not covered by this description.
1. First embodiment: solid-state imaging apparatus
   1-1. Overall configuration of the solid-state imaging apparatus
   1-2. Pixel circuit configuration
   1-3. Configurations of the major parts
   1-4. Alternative examples
2. Second embodiment: electronic device as an application example

### 1. First Embodiment: Solid-State Imaging Apparatus

### 1-1. Overall Configuration of the Solid-State Imaging Apparatus

A solid-state imaging apparatus 1 (“light detection apparatus” in a broad sense) as a first embodiment of the present disclosure is explained below. FIG. 1 is an overall configuration diagram of the solid-state imaging apparatus 1 as the first embodiment.

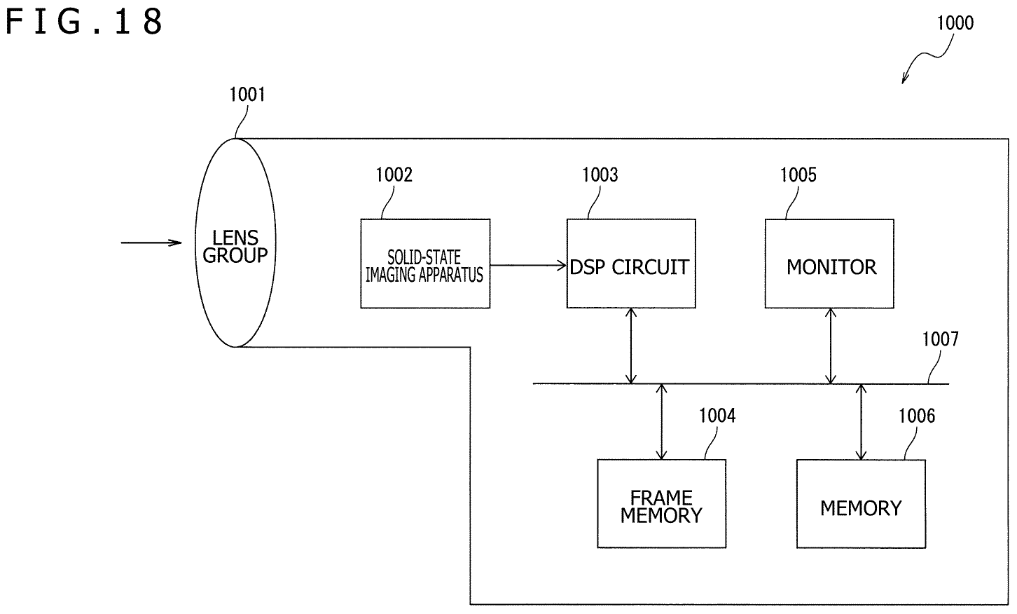

The solid-state imaging apparatus 1 in FIG. 1 is a back-illuminated CMOS (Complementary Metal Oxide Semiconductor) image sensor. As depicted in FIG. 18, the solid-state imaging apparatus 1 (1002) receives image light (incident light) from a subject via a lens group 1001, converts the quantity of the light incident on an imaging plane into electrical signals in units of pixels, and outputs the electrical signals as pixel signals.

As depicted in FIG. 1, the solid-state imaging apparatus 1 includes a substrate 2, a pixel region 3, a vertical drive circuit 4, column signal processing circuits 5, a horizontal drive circuit 6, an output circuit 7, and a control circuit 8.

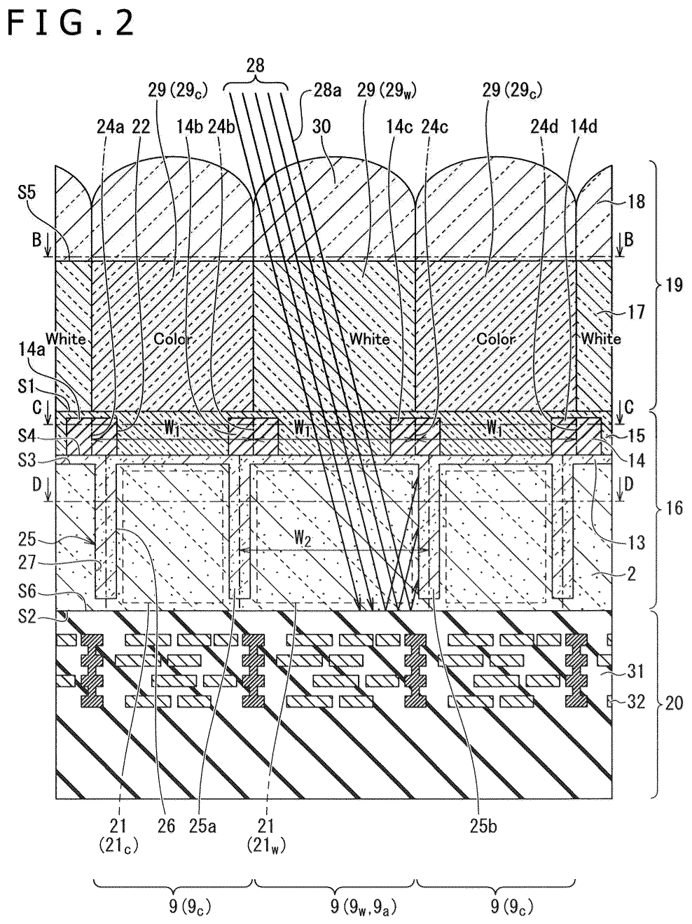

The pixel region 3 has multiple pixels 9 arrayed regularly in a two-dimensional array pattern (two-dimensional pattern) on the substrate 2. Each pixel 9 has multiple pixel transistors and a photoelectric conversion part 21 indicated in FIG. 2. Four types of transistors such as a transfer transistor, a reset transistor, an amplification transistor, and a selection transistor may be adopted as the multiple transistors. Alternatively, the three types of transistors with exception of the selection transistor may be adopted.

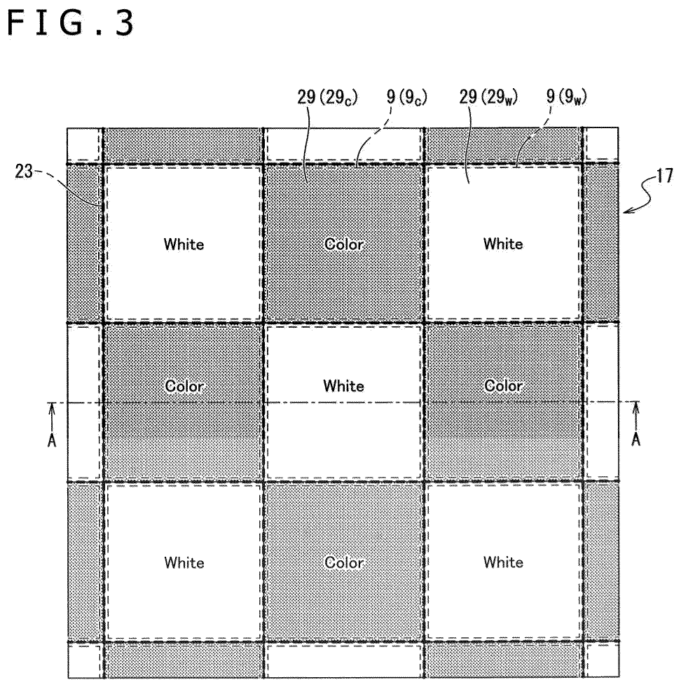

Also, as depicted in FIGS. 2 and 3, the pixels 9 include a white pixel 9w (“first pixel” in a broad sense) and a color pixel 9c (“second pixel” in a broad sense). The white pixel 9w has a color filter 29 that allows full-spectrum light to pass through. The color pixel 9c has a color filter 29 that allows the light in the wavelength region of a specific color to pass through. That is, the white pixel 9w may be said to be a pixel on which the full-spectrum light out of incident light 28 is incident.

The color pixel 9c may be said to be a pixel on which the light out of the incident light 28 having a peak wavelength in a wavelength region lower than a predetermined wavelength (e.g., lower limit of the infrared light wavelength region of 780 nm) is incident. As depicted in FIG. 3, the white pixel 9w and color pixel 9c are arrayed in such a pattern that a large number of them are staggered apart in their row and column directions so as not to overlap with one another.

The vertical drive circuit 4 includes shift registers, for example. The vertical drive circuit 4 selects a desired pixel drive line 10 and supplies a pulse signal onto the selected pixel drive line 10 to drive the pixel 9, thereby driving the pixels 9 in units of rows. That is, the vertical drive circuit 4 performs selection scans on the pixels 9 in the pixel region 3 in units of rows successively in the vertical direction, and supplies via vertical signal lines 11 the column signal processing circuits 5 with pixel signals based on a signal charge generated by the photoelectric conversion part 21 in each pixel 9 according to the amount of the light received by the photoelectric conversion part 21.

The column signal processing circuit 5 is provided for each column of the pixels 9, for example. Given signals from the pixels 9 of one row, the column signal processing circuits 5 perform signal processing such as noise removal on each pixel column. For example, the column signal processing circuits 5 carry out signal processing such as CDS (Correlated Double Sampling) and AD (Analog Digital) conversion to remove a fixed pattern noise specific to the pixels.

The horizontal drive circuit 6 includes shift registers, for example. The horizontal drive circuit 6 outputs horizontal scan pulses sequentially to the column signal processing circuits 5 to select them one by one, causing each column signal processing circuit 5 to output a pixel signal having undergone the signal processing onto a horizontal signal line 12.

The output circuit 7 performs signal processing on the pixel signal supplied successively from each of the column signal processing circuits 5 via the horizontal signal line 12, before outputting the processed pixel signals. The signal processing can involve, for example, buffering, black level adjustment, column variation correction, and various digital signal processes.

The control circuit 8 generates control signals as well as clock signals serving as the reference for the operations of the vertical drive circuit 4, the column signal processing circuits 5, and the horizontal drive circuit 6 on the basis of a vertical synchronization signal, a horizontal synchronization signal, and a master clock signal. The control circuit 8 outputs the clock signals and control signals thus generated to the vertical drive circuit 4, the column signal processing circuits 5, and the horizontal drive circuit 6.

### 1-3. Configurations of the Major Parts

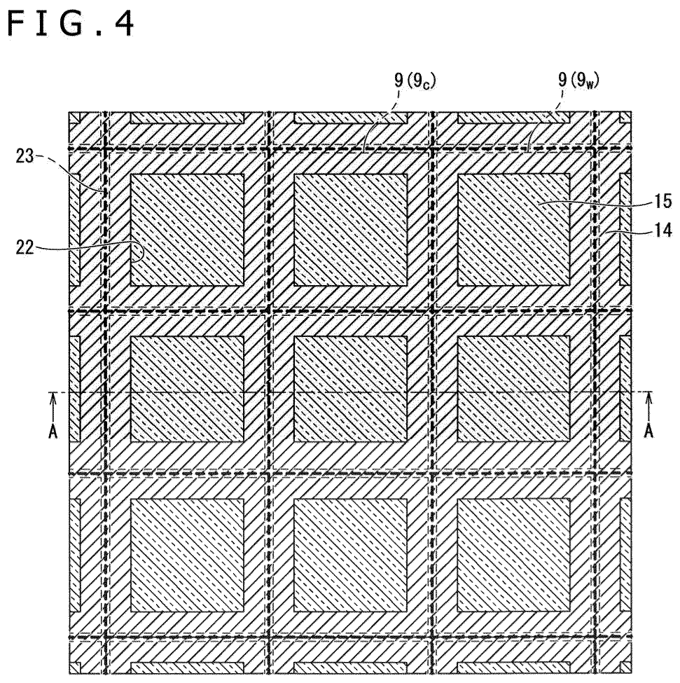

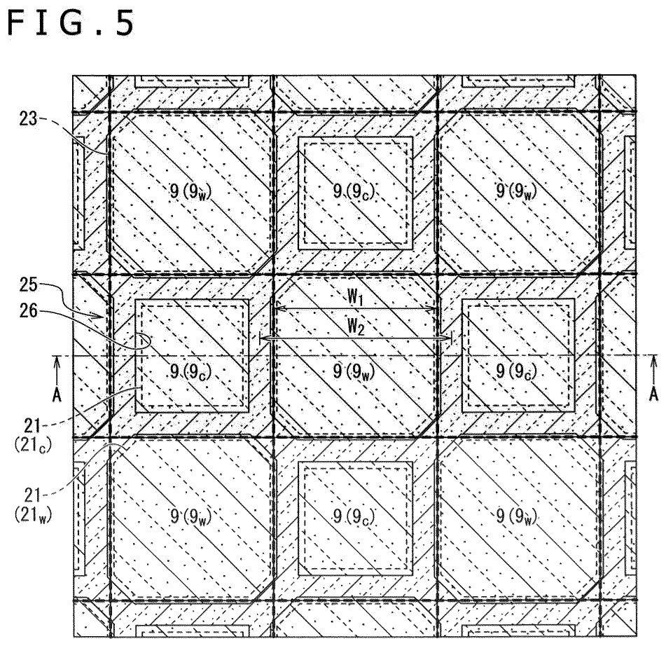

The structure of the solid-state imaging apparatus 1 in FIG. 1 is explained next in detail. FIG. 2 is a cross-sectional view of the solid-state imaging apparatus 1 taken on line A-A in FIG. 1. FIG. 3 is a plane structure view of the solid-state imaging apparatus 1 taken on line B-B in FIG. 2. FIG. 4 is a cross-sectional view of the solid-state imaging apparatus 1 taken on line C-C in FIG. 2. FIG. 5 is a cross-sectional view of the solid-state imaging apparatus 1 taken on line D-D in FIG. 2.

As depicted in FIG. 2, the solid-state imaging apparatus 1 has a light receiving layer 16 which is formed by stacking a substrate 2, an insulating film 13, a light blocking film 14, and a planarizing film 15 in this order. That surface of the light receiving layer 16 on the side of the planarizing film 15 (also referred to as “back side S1” hereunder) is provided with a light collecting layer 19 having a color filter layer 17 and a micro lens layer 18 stacked in this order. Further, that surface of the light receiving layer 16 on the side of the substrate 2 (also referred to as “front side S2” hereunder) is stacked with a wiring layer 20. That is, the wiring layer 20 may be said to be arranged opposite to the back side S3 of the substrate 2 (light receiving surface).

The substrate 2 includes a semiconductor substrate including silicon (Si), for example, to constitute the pixel region 3. The pixel region 3 has multiple pixels 9 arrayed in a two-dimensional pattern, each pixel 9 including a photoelectric conversion part 21 and four pixel transistors (not depicted). The photoelectric conversion part 21 includes a p-type semiconductor region formed on the front side S2 of the substrate 2 and an n-type semiconductor region formed on the back side S3 of the substrate 2, with a pn junction therebetween constituting a photodiode. In this configuration, each photoelectric conversion part 21 generates a signal charge according to the quantity of the incident light 28 on the photoelectric conversion part 21, and accumulates the generated signal charge in the n-type semiconductor region (charge storage region).

The insulating film 13 continuously covers the back side S3 of the substrate 2 and the inside of a trench 27.

The light blocking film 14 which is arranged on the back side S4 of the insulating film 13 is formed in a grid-like pattern having an opening 22 of the same shape for each pixel 9 (i.e., for each photoelectric conversion part 21), as depicted in FIG. 4. As illustrated in FIG. 4, the grid of the light blocking film 14 has multiple linear portions extended in the row direction (crosswise direction in FIG. 4) and arrayed at regular intervals in the column direction (vertical direction in FIG. 4), and multiple linear portions extended in the column direction and arrayed at regular intervals in the row direction. The linear portions have the same width each. This makes the opening 22 square in shape. In the description that follows, a line along the widthwise center of each linear portion will be referred to as “pixel boundary 23.” In such a configuration, as depicted in FIG. 2, the distances between the widthwise centers 24a, 24b, 24c and 24d of multiple cross sections 14a, 14b, 14c and 14d of the light blocking film 14 in parallel with the back side S3 of the substrate 2, the cross sections being perpendicular to the back side S3, are the same each (also referred to as “first distance W₁” hereunder). A light blocking material, for example, may be used as the material of the light blocking film 14. Such materials may include tungsten (W), aluminum (Al), and copper (Cu).

The planarizing film 15 continuously covers the entire back side S4 of the insulating film 13 including the light blocking film 14. This turns the back side S1 of the light receiving layer 16 into a plane with no unevenness.

A pixel separation part 25 is arranged between the adjacent photoelectric conversion parts 21. The pixel separation part 25, in a case of being viewed from the side of the micro lens layer 18, forms a grid-like pattern surrounding the pixels 9 (photoelectric conversion parts 21) as depicted in FIG. 5. The linear portions making up the grid of the pixel separation part 25 have the same width each. Also, in a case of being viewed from the side of the micro lens layer 18, an opening 26 of a grid cell (surrounding the photoelectric conversion part 21) of the pixel separation part 25 is shaped differently depending on the type of the surrounding pixel 9 (white pixel 9w or color pixel 9c).

Specifically, in the pixel separation part 25, the portion between the photoelectric conversion part 21 of the white pixel 9w (also referred to as “photoelectric conversion part 21w” hereunder) and the photoelectric conversion part 21 of the color pixel 9c (also referred to as “photoelectric conversion part 21c” hereunder) is formed closer to the photoelectric conversion part 21c than to the pixel boundary 23. This causes the portion (opening 26) surrounding the photoelectric conversion part 21c of the color pixel 9c to be square-shaped and smaller in size than the opening 22 of the light blocking film 14 (see FIG. 4). Also, in the pixel separation part 25, the portion between the photoelectric conversion parts 21w of white pixels 9w arranged in an oblique direction is formed linearly extending perpendicular to the oblique direction. The formation causes the portion (opening 26) surrounding the photoelectric conversion part 21w of the white pixel 9w to be octagon-shaped and larger in size than the opening 22 of the light blocking film 14. In such a configuration, as depicted in FIG. 2, the distance (also referred to as “second distance W₂” hereunder) between the widthwise centers of two cross sections 25a and 25b of the pixel separation part 25 that are perpendicular to the back side S3 of the substrate 2 and positioned surrounding the photoelectric conversion part 21w in the white pixel 9w is different from the first distance W₁. FIG. 2 depicts an exemplary case in which the second distance W₂ is made longer than the first distance W₁. In this case, the photoelectric conversion part 21w of the white pixel 9w is made larger in size than in a case where W₁=W₂. This improves the sensitivity of the white pixel 9w. The second distance W₂ may also be said to be the distance between the widthwise centers of two cross sections of the trench 27 that are perpendicular to the back side S3 of the substrate 2 and positioned surrounding the photoelectric conversion part 21w in the white pixel 9w.

The pixel separation part 25 has a bottomed trench 27 extending from the back side S3 of the substrate 2 toward the front side S2 (opposite side). That is, the trench 27 does not penetrate the substrate 2, allowing the bottom to be formed in the substrate 2. With the substrate 2 not penetrated by the trench 27, various elements and contacts may be arranged between the bottom of the pixel separation part 25 and the wiring layer 20. The trench 27 is formed in a grid-like pattern such that its inside surface and its bottom make up an external shape of the pixel separation part 25. The insulating film 13 covering the back side S3 of the substrate 2 is embedded inside the trench 27. The material to be adopted to make up the insulating film 13 may be a material with a refractive index different from that of the material of the substrate 2 (Si: refractive index of 3.9), for example. Such materials may include silicon oxide (SiO₂: refractive index of 1.5) and silicon nitride (SiN: refractive index of 2.0), for example. A large difference in refractive index between the photoelectric conversion part 21 and the insulating film 13 allows the interfacial boundary between the photoelectric conversion part 21 and the pixel separation part 25 to provide sufficient reflectivity. This can prevent the incident light 28 on the photoelectric conversion part 21 from passing through the pixel separation part 25 to leak to the adjacent photoelectric conversion part 21, thereby suppressing light color mixing. It is also possible electrically to isolate the adjacent photoelectric conversion parts 21 from each other and thereby to prevent the signal charge accumulated in one photoelectric conversion part 21 from leaking to the adjacent photoelectric conversion part 21.

The color filter layer 17 formed on the back side S1 of the planarizing film 15 has multiple color filters 29 arranged corresponding to the photoelectric conversion parts 21. As depicted in FIG. 3, the multiple color filters 29 include a color filter 29w that allows full-spectrum light out of the incident light 28 to pass through and a color filter 29c that allows that light out of the incident light 28 which has a peak wavelength in a wavelength region lower than a predetermined wavelength (e.g., lower limit of the infrared light wavelength region of 780 nm) to pass through (e.g., red light, green light, and blue light). Each of the multiple color filters 29 thus allows the light having a specific wavelength to pass through depending on the color filter type. The transmitted light is made incident on the corresponding photoelectric conversion part 21. In a case of being viewed from the side of the micro lens layer 18, each of the color filters 29 is square-shaped, the same in shape as the pixel boundary 23.

The micro lens layer 18 is formed on the back side S5 of the color filter layer 17 and has multiple micro lenses 30 arranged corresponding to the photoelectric conversion parts 21. In this arrangement, each of the micro lenses 30 collects image light from the subject (incident light 28) and causes the collected incident light 28 to efficiently enter the corresponding photoelectric conversion part 21 via the corresponding color filter 29. In a case of being viewed from the side of the micro lens layer 18, each micro lens 30 has the same shape (square) as that of the pixel boundary 23 and the color filter 29.

The wiring layer 20 formed on the front side S2 of the substrate 2 includes interlayer dielectric films 31 and wires 32 stacked in multiple layers with the interlayer dielectric films 31 interposed therebetween. The wiring layer 20 causes the wires 32 in multiple layers to drive the pixel transistors constituting each of the pixels 9.

In the solid-state imaging apparatus 1 configured as described above, light is irradiated from the back side S3 of the substrate 2 (from the back side S1 of the light receiving layer 16). The irradiated light is transmitted through the micro lenses 30 and the color filter 29. The light thus transmitted is subjected to photoelectric conversion by the photoelectric conversion part 21, which generates a signal charge. The generated signal charge is output as a pixel signal from the vertical signal line 11 formed by the wires 32 in the wiring layer 20 by way of the pixel transistors formed on the front side S2 of the substrate 2.

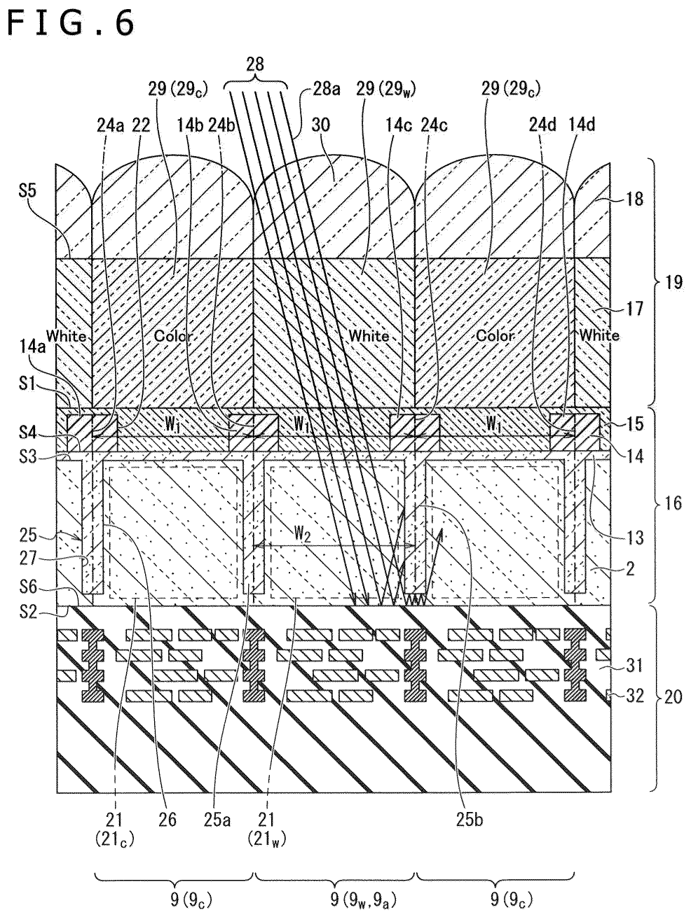

Long-wavelength light is not absorbed well by silicon (Si). Thus, when the light including infrared light out of the incident light 28 is incident on the photoelectric conversion part 21 of the solid-state imaging apparatus 1, the incident long-wavelength light (infrared light) is transmitted through the photoelectric conversion part 21 and reflected by the interfacial boundary between the substrate 2 and the wiring layer 20. Here, as depicted in FIG. 6, for example, attention is directed to that white pixel 9w of the solid-state imaging apparatus 1 (also referred to as “specific pixel 9a” hereunder) in which the first distance W1 and the second distance W2 are the same and in which, out of the incident light 28 (luminous flux) having passed through the photoelectric conversion part 21w, the reflected light, which is reflected by the interfacial boundary between the substrate 2 and the wiring layer 20, of the portion of the flux (light beam 28a) closest to the adjacent pixel passes closer to the wiring layer 20 than to the bottom of the pixel separation part 25 to exit to the adjacent photoelectric conversion part 21. In the solid-state imaging apparatus 1 in FIG. 6, the reflected light exiting from the specific pixel 9a to the adjacent photoelectric conversion part 21 can lead to the possibility of a drop in quantum efficiency QE. Also, the exited incident light 28, when detected by the adjacent photoelectric conversion part 21, may incur light color mixing (crosstalk).

In the first embodiment, by contrast, the first distance W₁ and the second distance W₂ in the white pixel 9w are made different from each other as depicted in FIG. 2. More specifically, the second distance W₂ is made longer than the first distance W₁. Consequently, in the white pixel 9w corresponding to the specific pixel 9a in FIG. 6, the light beam 28a reflected by the interfacial boundary between the substrate 2 and the wiring layer 20 hits the side surface of the pixel separation part 25 on the side of the photoelectric conversion part 21 and is reflected by the side surface, thus returning to the initial photoelectric conversion part 21. This can prevent the reflected light from entering the adjacent pixel 9 and thereby suppresses light color mixing (crosstalk). The reflected light returning to the initial photoelectric conversion part 21 is absorbed thereby, which improves quantum efficiency QE. This can provide the solid-state imaging apparatus 1 capable of suppressing light color mixing while enhancing quantum efficiency QE.

### 1-4. Alternative Examples

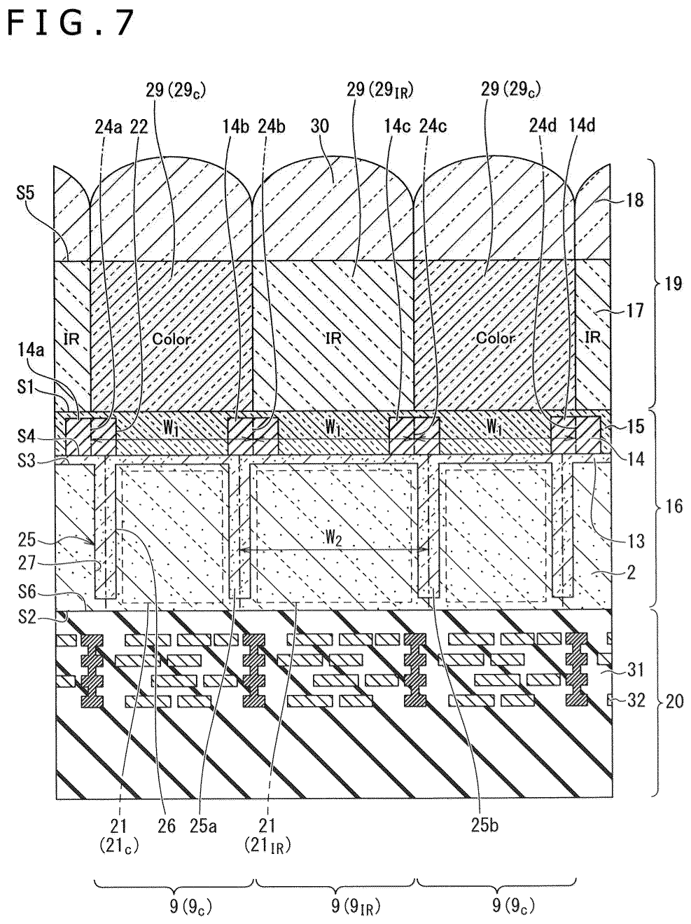

(1) Whereas the first embodiment has been described using the example in which the white pixel 9w is the first pixel, other configurations can alternatively be adopted. For example, as depicted in FIG. 7, the white pixel 9w may be replaced with an IR (Infrared radiation) pixel 9_{IR} having a color filter 29 allowing the light in the infrared light wavelength region (780 nm to 1 mm) out of the incident light 28 to pass through. Here, the IR pixel 9_{IR} may be said to be a pixel on which the light having a peak wavelength in a wavelength region equal to or higher than a predetermined wavelength (780 nm) is incident.

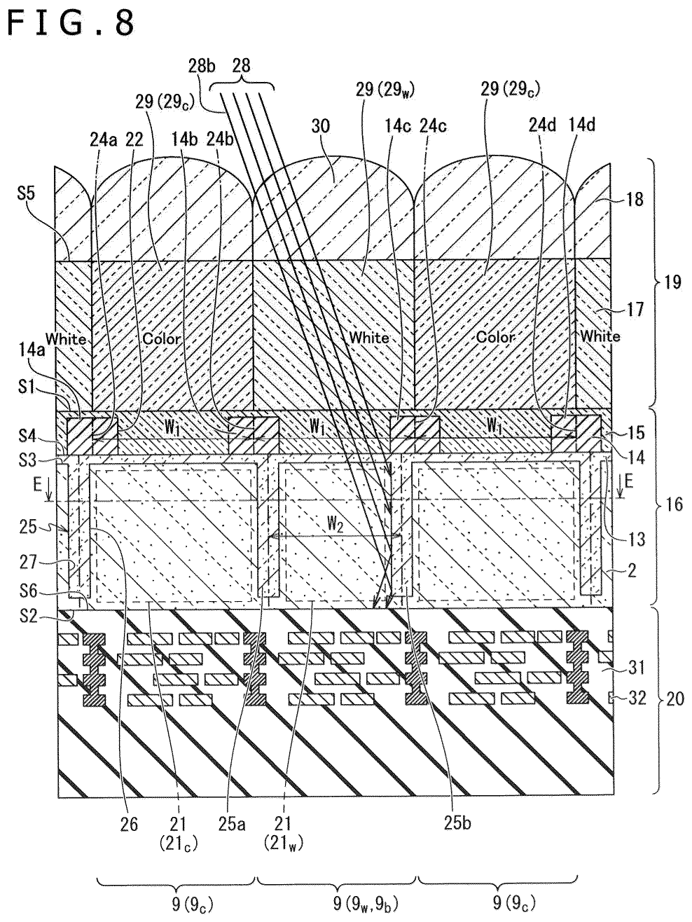

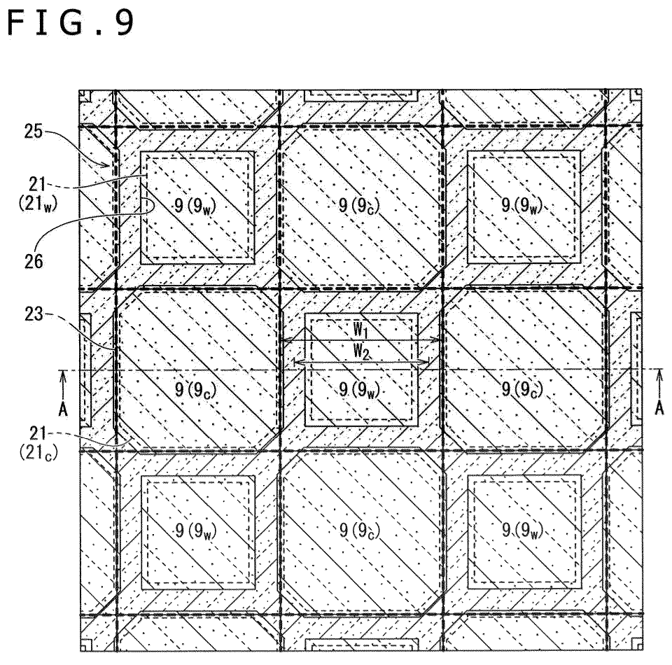

(2) Whereas the first embodiment has been described using the example in which the second distance W₂ is made longer than the first distance W₁ (W₂>W₁), other configurations may alternatively be adopted. In an alternative configuration, as depicted in FIGS. 8 and 9, the second distance W₂ may be made shorter than the first distance W₁ (W₂<W₁). In the example in FIG. 9, the opening 26 of the white pixel 9w is shaped to be a small square, and the opening 26 of the color pixel 9c is shaped to be a large octagon.

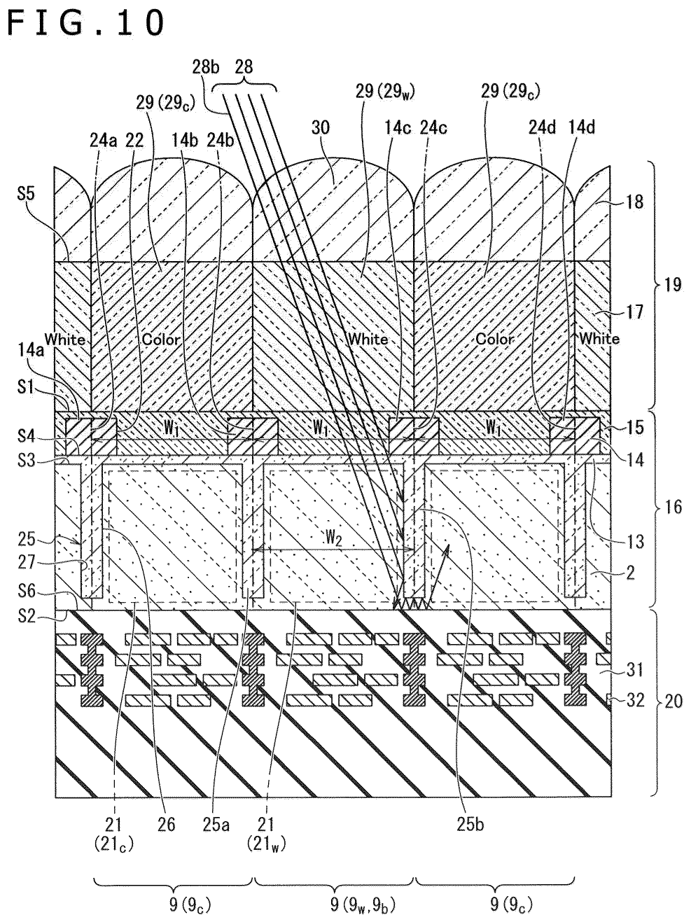

Here, as depicted in FIG. 10, attention is directed to the white pixel 9w of the solid-state imaging apparatus 1 (also referred to as “specific pixel 9b” hereunder) in which the first distance W₁ and the second distance W₂ are the same and in which, out of the incident light 28 (luminous flux) having passed through the photoelectric conversion part 21w, the reflected light, which is reflected by the interfacial boundary between the substrate 2 and the wiring layer 20, of the portion farthest from the adjacent pixel (light beam 28b) passes closer to the wiring layer 20 than to the bottom of the pixel separation part 25 to exit to the adjacent photoelectric conversion part 21. In the solid-state imaging apparatus 1 in FIG. 10, the reflected light exiting from the specific pixel 9b to the adjacent photoelectric conversion part 21 can lead to the possibility of a drop in quantum efficiency QE. Also, the exited incident light 28, when detected by the adjacent photoelectric conversion part 21, may incur light color mixing (crosstalk).

In this alternative example, by contrast, the first distance W₁ is made longer than the second distance W₂ in the white pixel 9w as depicted in FIG. 8. Consequently, in the white pixel 9w corresponding to the specific pixel 9b in FIG. 10, the light beam 28b hits the side surface of the pixel separation part 25 on the side of the photoelectric conversion part 21 and is reflected by the side surface, thus returning to the initial photoelectric conversion part 21. This can prevent the reflected light from entering the adjacent pixel 9 and thereby suppress light color mixing. The reflected light returning to the initial photoelectric conversion part 21 is absorbed thereby, which improves quantum efficiency QE.

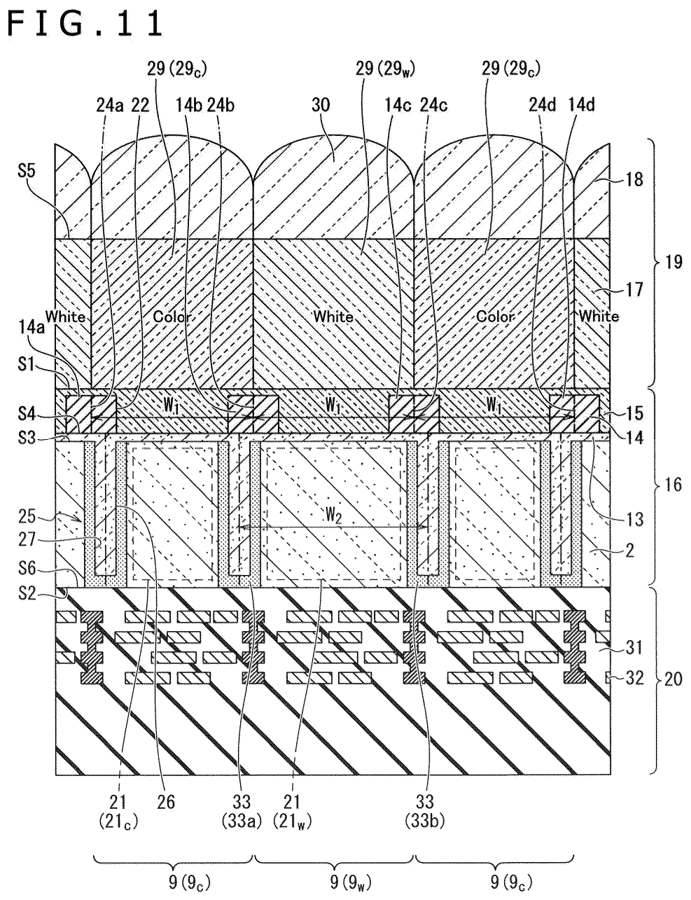

(3) Whereas the first embodiment has been described using the example where the trench 27 in which the insulating film 13 is embedded is used as the pixel separation part 25, other configurations can alternatively be adopted. For example, as depicted in FIG. 11, an alternative configuration may use, as the pixel separation part 25, a semiconductor region 33 with the conductivity type (p-type) opposite to that of the charge storage region (n-type semiconductor region) of the photoelectric conversion part 21 and the trench 27 formed in the semiconductor region 33. That is, the opposite conductivity type semiconductor region 33 is formed between the trench 27 and the photoelectric conversion part 21 as well as between the bottom of the trench 27 and the wiring layer 20. This configuration can reinforce pinning at the interfacial boundary between the photoelectric conversion part 21 and the pixel separation part 25 and thereby suppress the generation of dark current. The insulating film 13 is embedded in the trench 27 as in the case of the trench 27 of the first embodiment. In a case where the opposite conductivity type semiconductor region 33 is provided, the second distance W₂ may be the distance between the widthwise centers of two cross sections 33a and 33b of the opposite conductivity type semiconductor region 33 that are perpendicular to the back side S3 of the substrate 2 and positioned surrounding the photoelectric conversion part 21w in the white pixel 9w.

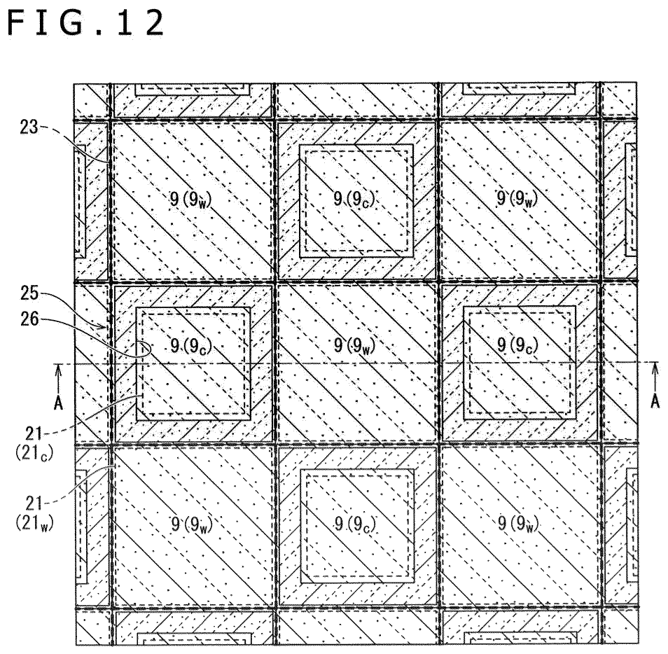

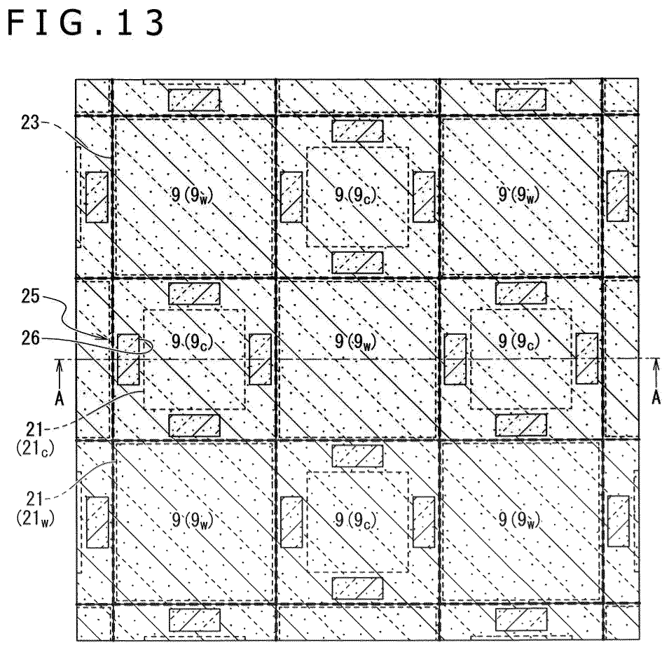

(4) The first embodiment has been described using the example in which the square shape for the portion (opening 26) surrounding the photoelectric conversion part 21c of the color pixel 9c and the octagon shape for the portion (opening 26) surrounding the photoelectric conversion part 21w of the white pixel 9w make up the grid pattern of the pixel separation part 25, as depicted in FIG. 5. Alternatively, other configurations may be adopted. Any grid pattern may be used for the pixel separation part 25 as long as the first distance W₁ and the second distance W₂ are made different from each other. For example, as depicted in FIG. 12, an alternative grid pattern may be one in which the pixel separation part 25 in FIG. 5 is deprived of the portion between the photoelectric conversion parts 21w of the white pixels 9w. In another alternative grid pattern, as depicted in FIG. 13, the pixel separation part 25 in FIG. 12 may be deprived of the corner portions of the square shape surrounding the photoelectric conversion part 21c of the color pixel 9c.

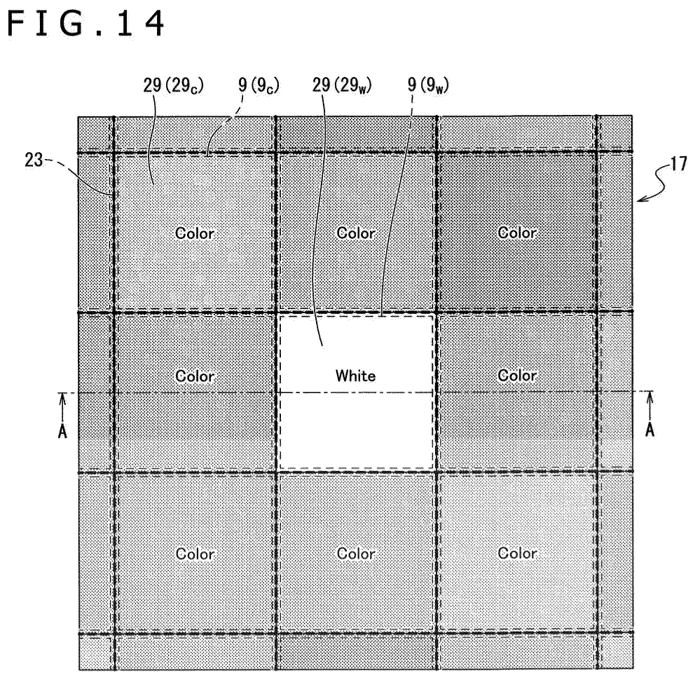

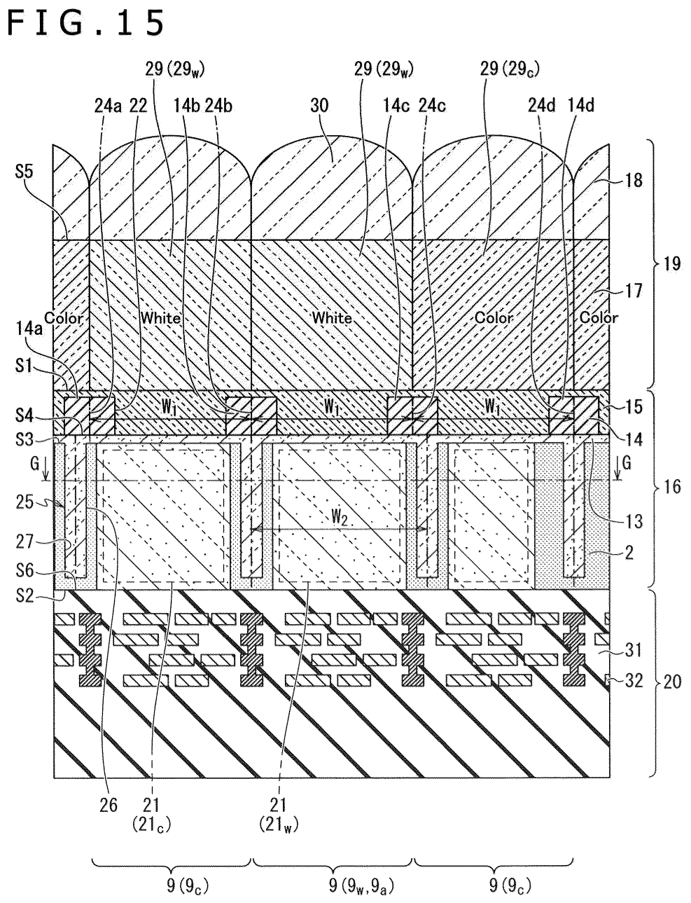

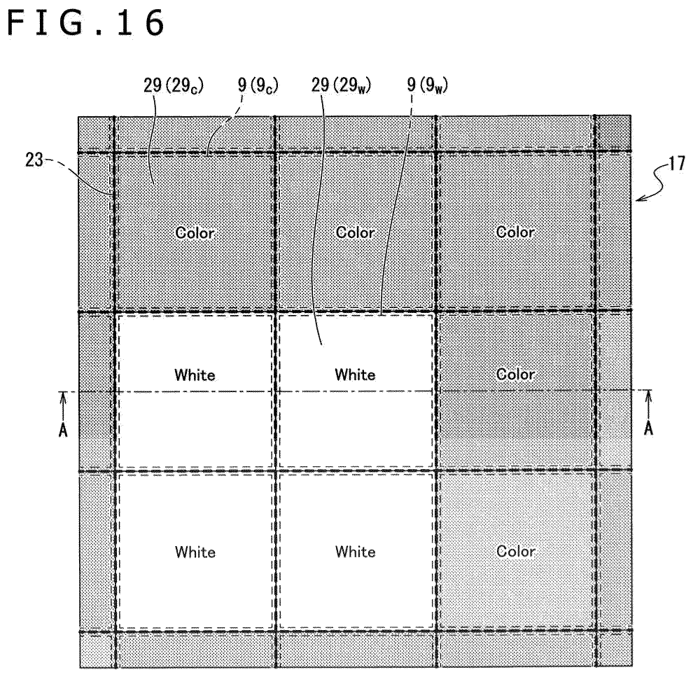

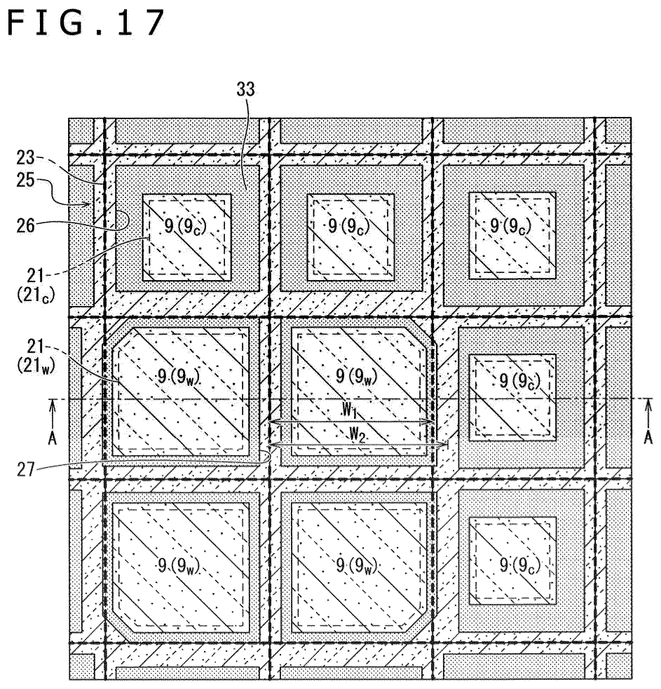

(5) The first embodiment has been described using the example in which a large number of the white pixels 9w and color pixels 9c are arrayed in a staggered pattern avoiding overlap therebetween as depicted in FIG. 3. Alternatively, other configurations may be adopted. Any array pattern may be used for the white pixels 9w and color pixels 9c. An alternative array pattern may include, as depicted in FIG. 14, portions each having one white pixel 9w surrounded by multiple color pixels 9c. Also, as depicted in FIGS. 15, 16 and 17, another alternative array pattern may include portions each having white pixels 9w arrayed adjacent to each other. In the example in FIGS. 16 and 17, two by two white pixels 9w are arrayed adjacent to each other.

Suppose that there are portions each having white pixels 9w arrayed adjacent to each other as depicted in FIG. 15. In such portions, the widthwise center 34a of the cross section 25a of the pixel separation part 25 perpendicular to the back side S3 of the substrate 2 and positioned between the photoelectric conversion parts 21w of adjacent white pixels 9w is made to overlap with the widthwise center 24b of the cross section 14b of the light blocking film 14 positioned on the back side S3 of the pixel separation part 25 in a case of being viewed from the back side S3 of the substrate 2. That is, as depicted in FIG. 17, the portion of the pixel separation part 25 between the photoelectric conversion parts 21w of adjacent white pixels 9w is formed in the same position as the pixel boundary 23. Likewise, the widthwise center 34b of the cross section 25c of the pixel separation part 25 between the photoelectric conversion parts 21c of adjacent color pixels 9c is made to overlap with the widthwise center 24d of the cross section 14d of the light blocking film 14 positioned on the back side S3 of the pixel separation part 25 in a case of being viewed from the back side S3 of the substrate 2. That is, as depicted in FIG. 17, the portion of the pixel separation part 25 between the photoelectric conversion parts 21c of adjacent color pixels 9c is formed in the same position as the pixel boundary 23.

Also, in a case where the pixel separation part 25 is structured to have the opposite conductivity type semiconductor region 33 in FIG. 11 as depicted in FIG. 17, the width W₃ of the opposite conductivity type semiconductor region 33 in the pixel separation part 25 between the photoelectric conversion parts 21c of adjacent color pixels 9c may be made different from the width W₄ of the opposite conductivity type semiconductor region 33 in the pixel separation part 25 between the photoelectric conversion part 21w of a white pixel 9w and the photoelectric conversion part 21c of a color pixel 9c, the pixels 9w and 9c being adjacent to each other, in order to give the same volume to the charge storage regions in the photoelectric conversion parts 21c of the color pixels 9c. For example, the width W₃ of the pixel separation part 25 between adjacent color pixels 9c is made larger than the width W₄ of the pixel separation part 25 between a color pixel 9c and a white pixel 9w. This makes it possible to render the width of the trench 27 identical while giving the same volume to the charge storage regions of the photoelectric conversion parts 21c in the color pixels 9c.

(6) This technology can be applied to all light detection apparatuses including distance measuring sensors known as ToF (Time of Flight) sensors, in addition to the above-described solid-state imaging apparatus serving as an image sensor. The distance measuring sensor emits irradiation light to an object, detects reflected light returning from the surface of the object, and calculates the distance to the object based on the time of flight from the time the irradiation light is emitted until the reflected light is received. The structure of the above-described pixels 9 can be adopted as the structure of light receiving pixels of this type of distance measuring sensor.

### 2. Second Embodiment: Electronic Device as an Application Example

The technology of the present disclosure (i.e., the present technology) may be applied to diverse electronic devices. FIG. 18 is a schematic configuration diagram of an imaging apparatus (video camera, digital still camera, etc.) serving as the electronic device to which the present disclosure is applied.

As depicted in FIG. 18, an imaging apparatus 1000 includes a lens group 1001, a solid-state imaging apparatus 1002 (i.e., solid-state imaging apparatus 1 of the first embodiment), a DSP (Digital Signal Processor) circuit 1003, a frame memory 1004, a monitor 1005, and a memory 1006. The DSP circuit 1003, the frame memory 1004, the monitor 1005, and the memory 1006 are interconnected via a bus line 1007.

The lens group 1001 leads incident light (image light) from the subject into the solid-state imaging apparatus 1002 to form an image on the light receiving surface (pixel region) thereof.

The solid-state imaging apparatus 1002 includes a CMOS image sensor in the form of the above-described first embodiment. The solid-state imaging apparatus 1002 converts the quantity of the incident light focused on the light receiving surface by the lens group 1001 into electrical signals in units of pixels, thereby generating pixel signals and supplying them to the DSP circuit 1003.

The DSP circuit 1003 performs predetermined signal processing on the pixel signals fed from the solid-state imaging apparatus 1002. The DSP circuit 1003 supplies the pixel signals having undergone the image processing to the frame memory 1004 in units of frames for temporary storage in the frame memory 1004.

The monitor 1005 includes a panel-type display apparatus such as a liquid crystal display panel or an organic EL (Electro Luminescence) panel. The monitor 1005 displays an image (video) of the subject based on the pixel signals stored temporarily in the frame memory 1004 in units of frames.

The memory 1006 includes a DVD or a flash memory, for example. The memory 1006 retrieves the pixel signals stored temporarily in units of frames in the frame memory 1004 and records the retrieved pixel signals.

The imaging apparatus 1000 is not limitative of the electronic device to which the solid-state imaging apparatus 1 can be applied. The solid-state imaging apparatus 1 can also be used in other electronic devices.

Whereas the solid-state imaging apparatus 1002 is configured as the solid-state imaging apparatus 1 of the first embodiment, other configurations can alternatively be adopted. For example, the solid-state imaging apparatus 1002 may be configured using the solid-state imaging apparatus 1 of the first embodiment or some other light detection apparatus to which the present technology is applied.

The present technology can also adopt the following configurations.

(1)

A light detection apparatus including:
a substrate;
multiple pixels configured to be arrayed two-dimensionally on the substrate and each have a photoelectric conversion part;
a light blocking film configured to be arranged on a side of a light receiving surface of the substrate and have an opening of the same shape for each of the pixels; and
a pixel separation part configured to be arranged between the photoelectric conversion parts on the substrate and have a trench, in which,
a distance between widthwise centers of two of multiple cross sections of the light blocking film in parallel with the light receiving surface of the substrate, the cross sections being perpendicular to the light receiving surface and passing through centers of adjacent two of the openings, the two cross sections further being positioned surrounding the openings, is a first distance constituting the same distance,
the multiple pixels include a first pixel and a second pixel, the first pixel receiving, out of incident light thereon, either full-spectrum light or light having a peak wavelength in a wavelength region equal to or higher than a predetermined wavelength, the second pixel receiving, out of the incident light thereon, light having a peak wavelength in a wavelength region lower than the predetermined wavelength, and
a distance between the widthwise centers of two cross sections of the pixel separation part that pass through the centers of adjacent two of the openings, the two cross sections being perpendicular to the light receiving surface of the substrate and positioned surrounding the photoelectric conversion part in the first pixel, is a second distance different from the first distance.
   (2)

The light detection apparatus according to (1), in which the predetermined wavelength is 780 nm.

(3)

The light detection apparatus according to (2), in which the first pixel is either a white pixel or an IR pixel.

(4)

The light detection apparatus according to any one of (1) to (3), in which the second distance is longer than the first distance.

(5)

The light detection apparatus according to any one of (1) to (3), in which the second distance is shorter than the first distance.

(6)

The light detection apparatus according to any one of (1) to (5), in which the second distance is a distance between the widthwise centers of two cross sections of the trench that are positioned surrounding the photoelectric conversion part in the first pixel, the two cross sections being perpendicular to the light receiving surface of the substrate and passing through the centers of adjacent two of the openings.

(7)

The light detection apparatus according to any one of (1) to (5), in which
the pixel separation part is formed between the photoelectric conversion parts on the substrate, includes a semiconductor region having a conductivity type opposite to that of a charge storage region of the photoelectric conversion parts, and has the trench formed in the semiconductor region, and
the second distance is a distance between the widthwise centers of two cross sections of the opposite conductivity type semiconductor region that are positioned surrounding the photoelectric conversion part in the first pixel, the two cross sections being perpendicular to the light receiving surface of the substrate and passing through the centers of adjacent two of the openings.
   (8)

The light detection apparatus according to any one of (1) to (7), in which
the widthwise center of the cross section of the pixel separation part between the photoelectric conversion parts of adjacent first pixels, the cross section being perpendicular to the light receiving surface of the substrate and passing through the centers of adjacent two of the openings, overlaps with the widthwise center of the cross section of the light blocking film positioned on the light receiving surface side of the pixel separation part in a case of being viewed from the light receiving surface side of the substrate, and
the widthwise center of the cross section of the pixel separation part between the photoelectric conversion parts of adjacent second pixels, the cross section being perpendicular to the light receiving surface of the substrate and passing through the centers of adjacent two of the openings, overlaps with the widthwise center of the cross section of the light blocking film positioned on the light receiving surface side of the pixel separation part in a case of being viewed from the light receiving surface side of the substrate.
   (9)

The light detection apparatus according to (8), in which
the pixel separation part is formed between the photoelectric conversion parts on the substrate, includes a semiconductor region having a conductivity type opposite to that of a charge storage region of the photoelectric conversion parts, and has the trench formed in the semiconductor region, and
a width of the opposite conductivity type semiconductor region in the pixel separation part between the photoelectric conversion parts of adjacent second pixels is made different from a width of the opposite conductivity type semiconductor region in the pixel separation part between the photoelectric conversion part of the first pixel and the photoelectric conversion part of the second pixel, the first and the second pixels being adjacent to each other, in order to give the same volume to the charge storage region in the photoelectric conversion part of each second pixel.
   (10)

An electronic device including:
a light detection apparatus including a substrate, multiple pixels configured to be arrayed two-dimensionally on the substrate and each have a photoelectric conversion part, a light blocking film configured to be arranged on the side of a light receiving surface of the substrate and have an opening of the same shape for each of the pixels, and a pixel separation part configured to be arranged between the photoelectric conversion parts on the substrate and have a trench, in which
the multiple pixels include a first pixel and a second pixel, the first pixel receiving, out of incident light thereon, either full-spectrum light or light having a peak wavelength in a wavelength region equal to or higher than a predetermined wavelength, the second pixel receiving, out of the incident light thereon, light having a peak wavelength in a wavelength region lower than the predetermined wavelength, a distance between the widthwise centers of two of multiple cross sections of the light blocking film in parallel with the light receiving surface of the substrate, the cross sections being perpendicular to the light receiving surface and passing through the centers of adjacent two of the openings, the two cross sections further being positioned surrounding the openings, is a first distance constituting the same distance, and the distance between the widthwise centers of two cross sections of the pixel separation part that pass through the centers of adjacent two of the openings, the two cross sections being perpendicular to the light receiving surface of the substrate and positioned surrounding the photoelectric conversion part in the first pixel, is a second distance different from the first distance.

### REFERENCE SIGNS LIST

1: Solid-state imaging apparatus
2: Substrate
3: Pixel region
4: Vertical drive circuit
5: Column signal processing circuit
6: Horizontal drive circuit
7: Output circuit
8: Control circuit
9: Pixel
9_{IR}: IR pixel
9a: Specific pixel
9b: Specific pixel
9c: Color pixel
9w: White pixel
10: Pixel drive line
11: Vertical signal line
12: Horizontal signal line
13: Insulating film
14: Light blocking film
14a-14d: Cross section
15: Planarizing film
16: Light receiving layer
17: Color filter layer
18: Micro lens layer
19: Light collecting layer
20: Wiring layer
21: Photoelectric conversion part
21c: Photoelectric conversion part of color pixel
21w: Photoelectric conversion part of white pixel
22: Opening
23: Pixel boundary
24a-24d: Widthwise center
25: Pixel separation part
25a-25c: Cross section
26: Opening
27: Trench
28: Incident light
28a, 28b: Light beam
29: Color filter
29c: Color filter of color pixel
29w: Color filter of white pixel
30: Micro lens
31: Interlayer dielectric film
32: Wires
33: Semiconductor region
33a, 33b: Cross section
34a, 34b: Widthwise center

1. A light detection apparatus comprising:
a substrate;
multiple pixels configured to be arrayed two-dimensionally on the substrate and each have a photoelectric conversion part;
a light blocking film configured to be arranged on a side of a light receiving surface of the substrate and have an opening of a same shape for each of the pixels; and
a pixel separation part configured to be arranged between the photoelectric conversion parts on the substrate and have a trench, wherein,
a distance between widthwise centers of two of multiple cross sections of the light blocking film in parallel with the light receiving surface of the substrate, the cross sections being perpendicular to the light receiving surface and passing through centers of adjacent two of the openings, the two cross sections further being positioned surrounding the openings, is a first distance constituting the same distance,
the multiple pixels include a first pixel and a second pixel, the first pixel receiving, out of incident light thereon, either full-spectrum light or light having a peak wavelength in a wavelength region equal to or higher than a predetermined wavelength, the second pixel receiving, out of the incident light thereon, light having a peak wavelength in a wavelength region lower than the predetermined wavelength, and
a distance between the widthwise centers of two cross sections of the pixel separation part that pass through the centers of adjacent two of the openings, the two cross sections being perpendicular to the light receiving surface of the substrate and positioned surrounding the photoelectric conversion part in the first pixel, is a second distance different from the first distance.

2. The light detection apparatus according to claim 1, wherein the predetermined wavelength is 780 nm.

3. The light detection apparatus according to claim 2, wherein the first pixel is either a white pixel or an IR pixel.

4. The light detection apparatus according to claim 1, wherein the second distance is longer than the first distance.

5. The light detection apparatus according to claim 1, wherein the second distance is shorter than the first distance.

6. The light detection apparatus according to claim 1, wherein the second distance is a distance between the widthwise centers of two cross sections of the trench that are positioned surrounding the photoelectric conversion part in the first pixel, the two cross sections being perpendicular to the light receiving surface of the substrate and passing through the centers of adjacent two of the openings.

7. The light detection apparatus according to claim 1, wherein
the pixel separation part is formed between the photoelectric conversion parts on the substrate, includes a semiconductor region having a conductivity type opposite to that of a charge storage region of the photoelectric conversion parts, and has the trench formed in the semiconductor region, and
the second distance is a distance between the widthwise centers of two cross sections of the opposite conductivity type semiconductor region that are positioned surrounding the photoelectric conversion part in the first pixel, the two cross sections being perpendicular to the light receiving surface of the substrate and passing through the centers of adjacent two of the openings.

8. The light detection apparatus according to claim 1, wherein
the widthwise center of the cross section of the pixel separation part between the photoelectric conversion parts of adjacent first pixels, the cross section being perpendicular to the light receiving surface of the substrate and passing through the centers of adjacent two of the openings, overlaps with the widthwise center of the cross section of the light blocking film positioned on the light receiving surface side of the pixel separation part in a case of being viewed from the light receiving surface side of the substrate, and
the widthwise center of the cross section of the pixel separation part between the photoelectric conversion parts of adjacent second pixels, the cross section being perpendicular to the light receiving surface of the substrate and passing through the centers of adjacent two of the openings, overlaps with the widthwise center of the cross section of the light blocking film positioned on the light receiving surface side of the pixel separation part in a case of being viewed from the light receiving surface side of the substrate.

9. The light detection apparatus according to claim 8, wherein
the pixel separation part is formed between the photoelectric conversion parts on the substrate, includes a semiconductor region having a conductivity type opposite to that of a charge storage region of the photoelectric conversion parts, and has the trench formed in the semiconductor region, and
a width of the opposite conductivity type semiconductor region in the pixel separation part between the photoelectric conversion parts of adjacent second pixels is made different from a width of the opposite conductivity type semiconductor region in the pixel separation part between the photoelectric conversion part of the first pixel and the photoelectric conversion part of the second pixel, the first and the second pixels being adjacent to each other, in order to give a same volume to the charge storage region in the photoelectric conversion part of each second pixel.

10. An electronic device comprising:
a light detection apparatus including a substrate, multiple pixels configured to be arrayed two-dimensionally on the substrate and each have a photoelectric conversion part, a light blocking film configured to be arranged on the side of a light receiving surface of the substrate and have an opening of a same shape for each of the pixels, and a pixel separation part configured to be arranged between the photoelectric conversion parts on the substrate and have a trench, wherein
the multiple pixels include a first pixel and a second pixel, the first pixel receiving, out of incident light thereon, either full-spectrum light or light having a peak wavelength in a wavelength region equal to or higher than a predetermined wavelength, the second pixel receiving, out of the incident light thereon, light having a peak wavelength in a wavelength region lower than the predetermined wavelength, a distance between the widthwise centers of two of multiple cross sections of the light blocking film in parallel with the light receiving surface of the substrate, the cross sections being perpendicular to the light receiving surface and passing through the centers of adjacent two of the openings, the two cross sections further being positioned surrounding the openings, is a first distance constituting the same distance, and the distance between the widthwise centers of two cross sections of the pixel separation part that pass through the centers of adjacent two of the openings, the two cross sections being perpendicular to the light receiving surface of the substrate and positioned surrounding the photoelectric conversion part in the first pixel, is a second distance different from the first distance.
